(19) United States
(12) Patent Application Publication
(10) Pub. No.: US 2009/0117745 A1
(43) Pub. Date: May 7, 2009

(54) METHODS FOR SELECTIVELY ETCHING A BARRIER LAYER IN DUAL DAMASCENE APPLICATIONS

(76) Inventors: SIYI LI, Fremont, CA (US); Michael Armacost, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/934,285

(22) Filed: Nov. 2, 2007

(51) Int. Cl. H01L 21/311

(52) U.S. Cl. 438/710; 257/E21.249

(57) ABSTRACT

Methods for etching a dielectric barrier layer with high selectivity to a dielectric bulk insulating layer and/or a hardmask layer in a dual damascene structure are provided. In one embodiment, the method includes providing a substrate having a portion of a dielectric barrier layer exposed through a dielectric bulk insulating layer in an etch reactor, flowing a gas mixture containing SiF₄ gas into the reactor, and etching the exposed portion of the dielectric barrier layer selectively to the dielectric bulk insulating layer using a plasma formed from the gas mixture.

### BACKGROUND

1. Field of the Invention

The present invention generally relates to semiconductor processing technologies and, more specifically, to methods for etching a barrier layer in a dual damascene fabrication process.

2. Description of the Related Art

Integrated circuits have evolved into complex devices that can include millions of components (e.g., transistors, capacitors and resistors) on a single chip. The evolution of chip designs continually requires faster circuitry and greater circuit density. The demands for greater circuit density necessitate a reduction in the dimensions of the integrated circuit components.

As the dimensions of the integrated circuit components are reduced (e.g. to sub-micron dimensions), the materials used to fabricate such components must be carefully selected in order to obtain satisfaction levels of electrical performance. For example, when the distance between adjacent metal interconnects and/or the thickness of the dielectric bulk insulating material that isolates the interconnects have sub-micron dimensions, the potential for capacitive coupling occurs between the metal interconnects is high. Capacitive coupling between adjacent metal interconnects may cause cross talk and/or resistance-capacitance (RC) delay which degrades the overall performance of the integrated circuit and may render the circuit inoperable.

In order to minimize capacitive coupling between adjacent metal interconnects, low dielectric constant bulk insulating materials (e.g., dielectric constants less than about 4.0) are needed. Examples of low dielectric constant bulk insulating materials include silicon dioxide (SiO₂), silicate glass, fluorosilicate glass (FSG), and carbon doped silicon oxide (SiOC), among others.

In addition, a dielectric barrier layer is often utilized to separate the metal interconnects from the dielectric bulk insulating materials. The dielectric barrier layer minimizes the diffusion of the metal from the interconnect material into the dielectric bulk insulating material. Diffusion of the metal into the dielectric bulk insulating material is undesirable because such diffusion can affect the electrical performance of the integrated circuit, or render the circuit inoperative. The dielectric layer needs to have a low dielectric constant in order to maintain the low-k characteristic of the dielectric stack between conductive lines. The dielectric barrier layer also acts as an etch-stop layer for a dielectric bulk insulating layer etching process, so that the underlying metal will not be exposed to the etching environment. The dielectric barrier layer has a dielectric constant of about 5.5 or less. Examples of dielectric barrier layer are silicon carbide (SiC) and nitrogen containing silicon carbide (SiCN), among others.

Some integrated circuit components include multilevel interconnect structures (e.g., dual damascene structures). Multilevel interconnect structures can have two or more bulk insulating layers, low dielectric barrier layers, and metal layers stacked on top of one another. As an exemplary dual damascene structure 100 disposed on a substrate 102 shown in FIG. 1A, a dielectric bulk insulating layer 110 with an underlying dielectric barrier layer 108 are stacked on another previously formed interconnect with a conductive layer 106 embedded in another dielectric bulk insulating layer 104. A hardmask layer 112 may be optionally disposed on the formed dual damascene structure 100. As a via/trench etching process is completed and a via/trench 150 is defined in the dielectric bulk insulating layer 110, the surface 116 of the dielectric barrier layer 114 exposed by the via/trench 150 is subsequently removed to expose the upper surface 122 of the underlying conductive layer 106, as shown in FIG. 1B. However, the similarity of the materials selected for the bulk insulating layer 110, the hardmask layer 112 and dielectric barrier layer 108 results in similar etch properties therebetween, thereby causing poor selectivity during etching. As the dielectric barrier layer 108 is etched, the dielectric bulk insulating layer 110 and the hardmask layer 112 may be attacked by the reactive etchant species, resulting in non-uniformity or tapered profile on the top 128, 124 and/or sidewall 120, 126, of the hardmask layer 112 and the dielectric bulk insulating layer 110.

Therefore, there is a need for a method of etching a dielectric barrier layer with high selectivity to a dielectric bulk insulating layer and/or a hardmask layer.

### SUMMARY

Methods for etching a dielectric barrier layer with high selectivity to a dielectric bulk insulating layer and/or a hardmask layer in a dual damascene structure are provided in the present invention. In one embodiment, a method for etching a dielectric barrier layer includes providing a substrate having a portion of a dielectric barrier layer exposed through a dielectric bulk insulating layer in an etch reactor, flowing a gas mixture containing SiF₄ gas into the reactor, and etching the exposed portion of the dielectric barrier layer selectively to the dielectric bulk insulating layer using a plasma formed from the gas mixture.

In another embodiment, a method for etching a dielectric barrier layer in a dual damascene structure includes providing a substrate having a portion of a dielectric barrier layer exposed therethrough a dielectric bulk insulating layer in a reactor, wherein the dielectric barrier layer is a carbon and nitrogen containing silicon film, flowing a gas mixture containing SiF₄ gas into the reactor, and etching the exposed portion of the dielectric barrier layer in a presence of a plasma formed from the gas mixture.

In yet another embodiment, a method for etching a dielectric barrier layer in a dual damascene structure includes providing a substrate having a portion of a dielectric barrier layer exposed through a dielectric bulk insulating layer and a hardmask layer in a reactor, wherein the dielectric bulk insulating layer is a low-k material and the dielectric barrier layer is a carbon and nitrogen containing silicon film, flowing a gas mixture containing SiF₄ gas into the reactor, and etching the exposed portion of the dielectric layer selectively to the dielectric bulk insulating layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIGS. 1A-1B are sectional views of exemplary conventional interconnect structures;

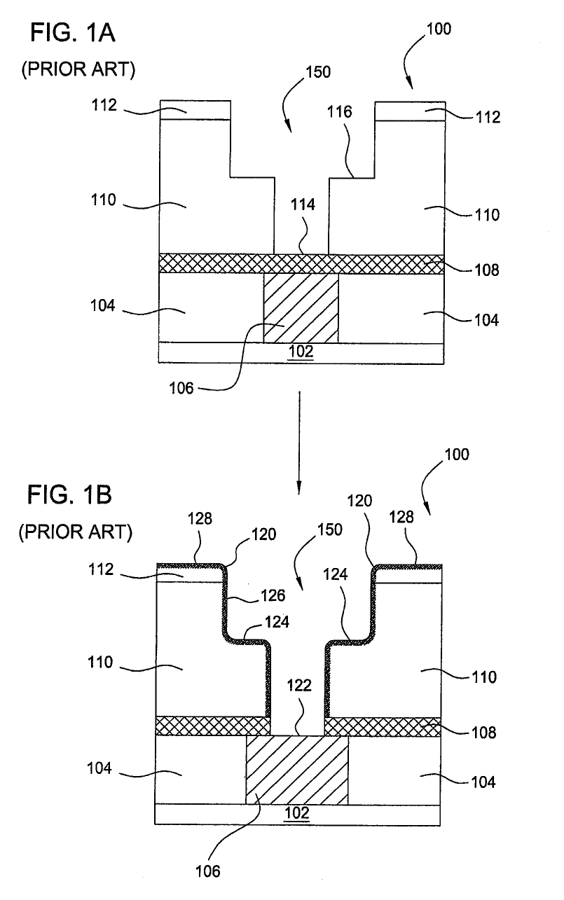

FIG. 2 is a schematic cross-sectional view of a plasma reactor used according to one embodiment of the invention;

FIG. 3 is a flow diagram of one embodiment of a dielectric barrier layer removal process on a dual damascene interconnect structure according to one embodiment of the invention; and

FIGS. 4A-4B are sectional views of one embodiment of an interconnect structure having an exposed dielectric barrier layer disposed on a substrate.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention include methods for etching a dielectric barrier layer with high selectivity to a dielectric bulk insulating layer and/or a hardmask layer. The methods preserve the profile and dimension of the features formed on a substrate by selectively etching the dielectric barrier layer substantially without attacking the adjacent dielectric bulk insulating layer and/or the hardmask layer and/or the underlying conductive layer.

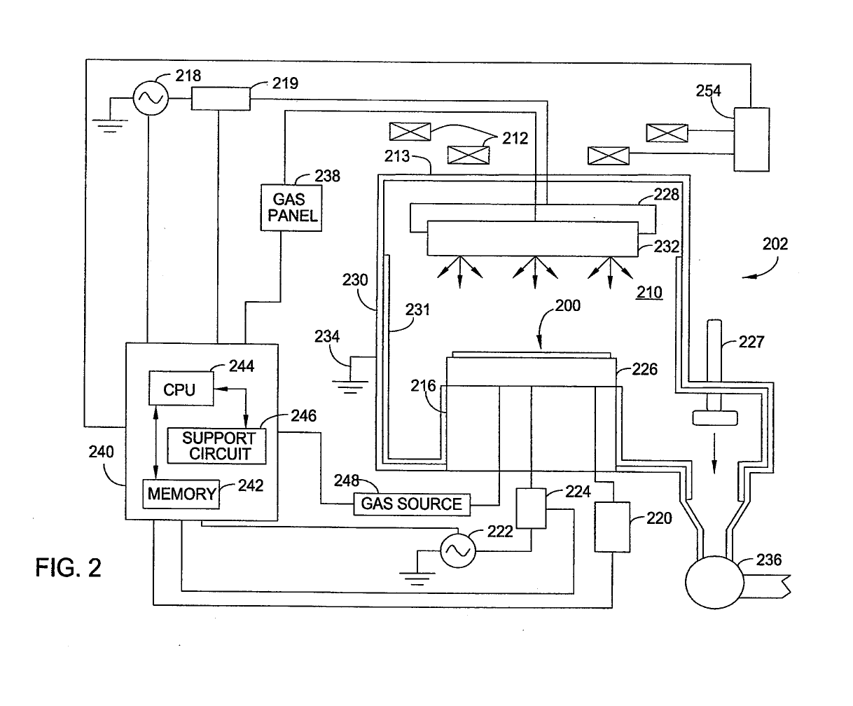

FIG. 2 depicts a schematic, cross-sectional diagram of one embodiment of a plasma source etch reactor 202 suitable for performing the dielectric barrier layer etch according to the present invention. One such etch reactor suitable for performing the invention is the ENABLER® processing chamber, available from Applied Materials, Inc., of Santa Clara, Calif. It is contemplated that the dielectric barrier layer etching process described herein may be performed in other etch reactors, including those from other manufacturers.

In one embodiment, the reactor 202 includes a process chamber 210, The process chamber 210 is a high vacuum vessel that is coupled through a throttle valve 227 to a vacuum pump 236. The process chamber 210 includes a conductive chamber wall 230. The temperature of the chamber wall 230 is controlled using liquid-containing conduits (not shown) that are located in and/or around the wall 230. The chamber wall 230 is connected to an electrical ground 234. A liner 231 is disposed in the chamber 210 to cover the interior surfaces of the walls 230. The liner 231 facilitates in-situ self-cleaning capabilities of the chamber 210, so that byproducts and residues deposited on the liner 231 can be readily removed.

The process chamber 210 also includes a support pedestal 216 and a showerhead 232. The support pedestal 216 is disposed below the showerhead 232 in a spaced-apart relation. The support pedestal 216 may include an electrostatic chuck 226 for retaining a substrate 200 during processing. Power to the electrostatic chuck 226 is controlled by a DC power supply 220.

The support pedestal 216 is coupled to a radio frequency (RF) bias power source 222 through a matching network 224. The bias power source 222 is generally capable of producing an RF signal having a tunable frequency of from about 50 kHz to about 60 MHz and a bias power of about 0 to 5,000 Watts. Optionally, the bias power source 222 may be a DC or pulsed DC source.

The temperature of the substrate 200 supported on the support pedestal 216 is at least partially controlled by regulating the temperature of the support pedestal 216. In one embodiment, the support pedestal 216 includes a channels formed therein for flowing a coolant. In addition, a backside gas, such as helium (He) gas, provided from a gas source 248, fits provided into channels disposed between the back side of the substrate 200 and grooves (not shown) formed in the surface of the electrostatic chuck 226. The backside He gas provides efficient heat transfer between the pedestal 216 and the substrate 200. The electrostatic chuck 226 may also include a resistive heater (not shown) within the chuck body to heat the chuck 226 during processing.

The showerhead 232 is mounted to a lid 213 of the processing chamber 210. A gas panel 238 is fluidly coupled to a plenum (not shown) defined between the showerhead 232 and the lid 213. The showerhead 232 includes a plurality of holes to allow gases provided to the plenum from the gas panel 238 to enter the process chamber 210. The holes in the showerhead 232 may be arranged in different zones such that various gases can be released into the chamber 210 with different volumetric flow rates.

The showerhead 232 and/or an upper electrode 228 positioned proximate thereto is coupled to an RF source power 218 through an impedance transformer 219 (e.g., a quarter wavelength matching stub). The RF source power 218 is generally capable of producing an RF signal having a tunable frequency of about 160 MHz and a source power of about 0 to 5,000 Watts.

The reactor 202 may also include one or more coil segments or magnets 212 positioned exterior to the chamber wall 230, near the chamber lid 213. Power to the coil segment(s) 212 is controlled by a DC power source or a low-frequency AC power source 254.

During substrate processing, gas pressure within the interior of the chamber 210 is controlled using the gas panel 238 and the throttle valve 227. In one embodiment, the gas pressure within the interior of the chamber 210 is maintained at about 0.1 to 999 mTorr. The substrate 200 may be maintained at a temperature of between about 10 to about 500 degrees Celsius.

A controller 240, including a central processing unit (CPU) 244, a memory 242, and support circuits 246, is coupled to the various components of the reactor 202 to facilitate control of the processes of the present invention. The memory 242 can be any computer-readable medium, such as random access memory (RAM), read only memory (ROM), floppy disk, hard disk, or any other form of digital storage, local or remote to the reactor 202 or CPU 244. The support circuits 246 are coupled to the CPU 244 for supporting the CPU 244 in a conventional manner. These circuits include cache, power supplies, clock circuits, input/output circuitry and subsystems, and the like. A software routine or a series of program instructions stored in the memory 242, when executed by the CPU 244, causes the reactor 202 to perform an etch process of the present invention.

FIG. 2 only shows one exemplary configuration of various types of plasma reactors that can be used to practice the invention. For example, different types of source power and bias power can be coupled into the plasma chamber using different coupling mechanisms. Using both the source power and the bias power allows independent control of a plasma density and a bias voltage of the substrate with respect to the plasma. In some applications, the source power may not be needed and the plasma is maintained solely by the bias power. The plasma density can be enhanced by a magnetic field applied to the vacuum chamber using electromagnets driven with a low frequency (e.g., 0.1-0.5 Hertz) AC current source or a DC source. In other applications, the plasma may be generated in a different chamber from the one in which the substrate is located, e.g., remote plasma source, and the plasma subsequently guided into the chamber using techniques known in the art.

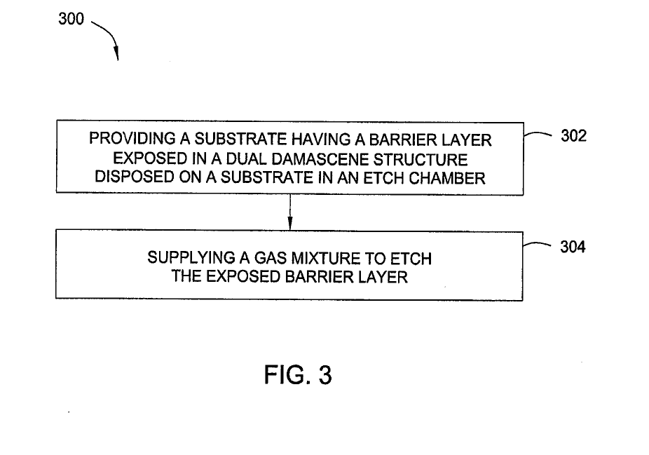

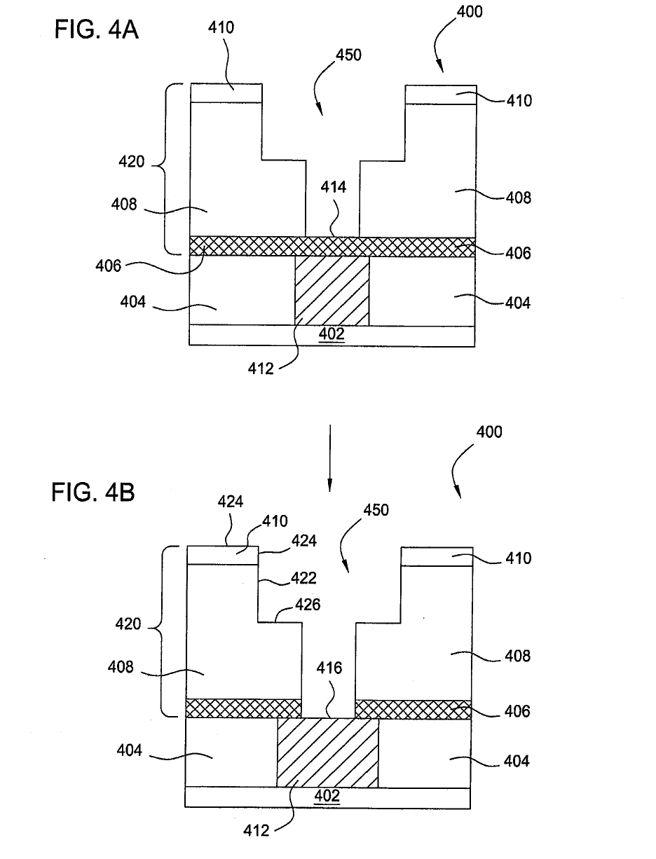

FIG. 3 illustrates a flow diagram of one embodiment of a dielectric barrier layer removal process 300 according to one embodiment of the invention. FIGS. 4A-4B are schematic cross-sectional views illustrating the sequence of the dielectric barrier layer removal process 300. The process 300 may be stored in memory 242 as instructions that executed by the controller 240 to cause the process 300 to be performed in a plasma processing chamber, such as the reactor 202 or other suitable etch reactor.

The process 300 begins at a block 302 by providing a substrate 402 having a dielectric barrier layer 406 in a dual damascene structure 400 in the reactor 202. A dielectric stack 420, as shown in FIG. 4A, is disposed on an interconnect layer having at least one conductive layer 412, such as copper line, disposed laterally bounded by a dielectric layer 404. The dielectric stack 420 includes a dielectric bulk insulating layer 408 disposed over a dielectric barrier layer 406. An optional hardmask layer 410 may be disposed on the top of the dielectric bulk insulating layer 408. A trench/via 450 is formed in the dielectric bulk insulating layer 408 by a suitable etching process, such as dual damascene etching process. In one embodiment, the dielectric bulk insulating layer 408 is a dielectric material having a dielectric constant less than 4.0 (e.g., a low-k material). Examples of suitable materials include carbon-containing silicon oxides (SiOC), such as BLACK DIAMOND® dielectric material available from Applied Materials, Inc., and other low-k polymers, such as polyamides. The optional hardmask layer 410 disposed on the dielectric bulk insulating layer 408 may be a dielectric layer selected from a group consisting of silicon oxide, TEOS, silicon oxynitride, amorphous carbon, and the like. In the embodiment depicted in FIG. 4A-B, the dielectric bulk insulating layer 408 is a carbon-containing silicon oxide (SiOC) layer and the hardmask layer 410 is a TEOS layer.

The dielectric barrier layer 406 has a dielectric constant of about 5.5 or less. In one embodiment, the dielectric barrier layer 406 is a carbon containing silicon layer (SiC), a nitrogen doped carbon containing silicon layer (SiCN), or the like. In the embodiment depicted in FIG. 4A, the dielectric barrier layer is a SiCN film. An example of the dielectric barrier layer material is BLOK® dielectric material, available from Applied Materials, Inc.

In the embodiment depicted in FIG. 4A, the dielectric stack 420 is etched through an opening, thereby defining a feature 450, such as a trench or via, in the dielectric bulk insulating layer 408 over the dielectric barrier layer 406. A portion of the dielectric bulk insulating layer 408 is removed to expose a surface 414 of the dielectric barrier layer 406. A conductive layer 412 present in the interconnect layer 404 is below the feature 450 formed in the dielectric barrier layer 406. In one embodiment, the dielectric bulk insulating layer 408 is etched using a plasma formed from fluorine and carbon. The dielectric bulk insulating layer 408 may be etched in an etch chamber, such as the reactor 202 described in FIG. 2 or other suitable reactor.

In one embodiment, the etch process may be performed by supplying carbon and fluorine containing gas, such as carbon tetrafluoride (CF₄), at between about 5 to about 250 sccm, applying a power between about 50 Watt to about 2000 Watt to maintain a plasma formed from the carbon and fluorine containing gas, maintaining a temperature between about 0 degrees Celsius to about 50 Celsius, and controlling process pressure between about 5 mTorr to about 200 mTorr into the reactor. In another embodiment, at least a carrier gas, such as argon (Ar), may also be supplied accompanying with the carbon and fluorine containing gas into the reactor. The carrier gas may be supplied between about 50 to about 500 sccm.

At block 304, a gas mixture containing silicon fluorine gas is supplied into the reactor 202 to etch the exposed dielectric barrier layer 406 and remove the dielectric barrier layer 406 from above the conductive layer 412 defined by the trench 450 in the dielectric bulk insulating layer 408 on the substrate 402, as shown in FIG. 4B. In the embodiment depicted in FIG. 4B, the silicon fluorine gas used to etch the dielectric barrier layer 406 is SiF₄ gas. The SiF₄ gas in the gas mixture is dissociated by the plasma generated in the reactor, forming silicon radicals and fluorine radicals. As the fluorine radicals etch the dielectric barrier layer 406, the silicon radicals may simultaneously adhere on the sidewalls 422, 424 and upper surface 426, 424 of the dielectric bulk insulating layer 408 and the hardmask layer 410, thereby protecting the dielectric bulk insulating layer 408 and the hardmask layer 410 from being attacked during the dielectric barrier layer removal process. Additionally, a small amount of oxygen containing gas may be supplied in the gas mixture to react with the silicon radicals, thereby assisting forming a protecting layer on the exposed surface of the dielectric bulk insulating layer 408 and the hardmask layer 410. Alternatively, a carbon fluorine containing gas may be optionally supplied in the gas mixture to assist forming a protective polymer to protect the exposed surface of the dielectric bulk insulating layer 408 and the hardmask layer 410 during etching. As the SiF₄ gas may provide both etchant reactive species and protective species while dissociated in the plasma, a high selectivity for the dielectric barrier layer 406 over the dielectric bulk insulating layer 408 and/or the hardmask layer 410 beneficially results.

In one embodiment, the silicon fluorine gas supplied in the gas mixture may include, but not limited to SiF₄. In another embodiment, the gas mixture may include a silicon fluorine gas and an oxygen containing gas. Examples of oxygen containing gas are O₂, N₂O, CO₂, NO₂ and the like. In yet another embodiment, the gas mixture may include a silicon fluorine gas, and a fluorine containing gas. Suitable examples of fluorine containing gas may include, but not limited to, CH₂F₂, CHF₃, CH₃F, C₂F₆, CF₄, C₃F₈, C₄F₆, C₄F₈, and the like. In the embodiment where the fluorine containing gas is included in the gas mixture, the oxygen containing gas may be optionally supplied. Optionally, the gas mixture may further include a carrier layer. Suitable examples of the carrier gas include H₂, N₂, Ar, He, Xe, Kr and the like.

Several process parameters are regulated while the barrier layer etch gas mixture is supplied into the etch reactor. In one embodiment, a pressure of the gas mixture in the etch reactor is regulated between about 10 mTorr to about 500 mTorr, for example, between about 50 mTorr to about 300 mTorr. The substrate temperature is maintained between about 0 degrees Celsius and about 65 degrees Celsius, for example, between about 0 degrees Celsius and about 45 degrees Celsius. The RF source power may be applied at a power of about 100 Watts to about 800 Watts, such as about 400 Watts, to provide a plasma from the gas mixture. The silicon fluorine gas, such as SiF₄ gas, may be provided at a flow rate between about 5 sccm to about 500 sccm, for example, about between about 20 sccm to about 100 sccm. The oxygen containing gas, such as O₂, may be provided at a flow rate between about 0 sccm to about 200 sccm, for example about 0 sccm to about 50 sccm. The fluorine containing gas, such as CHF₃, may be provided at a flow rate at a rate between about 0 sccm to about 80 sccm, for example, between about 0 sccm to about 20 sccm. The insert gas, such as Ar, may be provided at a flow rate between about 50 sccm to about 1000 sccm, for example about 100 sccm to about 500 sccm. The etching time may be processed at between about 10 seconds to about 60 seconds.

The etching dielectric barrier layer process with a SiF₄ containing gas mixture enables barrier layer 406 to be selectively etched in a manner without attacking the adjacent and/or dielectric bulk insulating layer 408 and/or the hardmask layer 410. The barrier etch gas mixture has a low selectivity to dielectric bulk insulating layer 408 and/or the hardmask layer 410 because the fluorine etchant free radicals react mostly with the dielectric barrier layer 406 while generating silicon protective free radical that protect the dielectric bulk insulating layer 408, thereby allowing the exposed dielectric barrier layer 406 defined by the trenches 450 to be uniformly etched without damage to the other exposed materials of the film stack. In one embodiment, the selectivity of the dielectric barrier layer 406 to the bulk insulating layer 408 is at least 3 and the selectivity of the dielectric barrier layer 406 to the hardmask layer 410 is at least about 5, such as greater than 6. In one embodiment, the etch rate using the present invention is about 360 Å per minute for etching the dielectric barrier layer 406, and about 160 Å per minute for etching the bulk insulating layer 408, and about 60 Å per minute for etching the hardmask layer 410.

The process of etching the dielectric barrier layer 406 is terminated after reaching an endpoint signaling that the underlying conductive layer 412 has been exposed. The endpoint may be determined by any suitable method. For example, the endpoint may be determined by monitoring optical emissions, expiration of a predefined time period or by another indicator for determining that the dielectric barrier layer 406 to be etched has been sufficiently removed.

Thus, the present invention provides an improved method for etching a dielectric barrier layer with high selectivity to a dielectric bulk insulating layer and/or the hardmask layer. The method advantageously preserves the profile and dimension of the features in a dual damascene structure by selectively etching the dielectric barrier layer defined by the trenches in dielectric bulk insulating layer.

While the foregoing is directed to embodiments of the present invention, other and further embodiments of the invention may be devised without departing from the basic scope thereof, and the scope thereof is determined by the claims that follow.

What is claimed is:

1. A method for etching a dielectric barrier layer in a dual damascene structure, comprising:
providing a substrate having a portion of a dielectric barrier layer exposed through a dielectric bulk insulating layer in an etch reactor;
flowing a gas mixture containing SiF₄ gas into the reactor; and
etching the exposed portion of the dielectric barrier layer selectively to the dielectric bulk insulating layer using a plasma formed from the gas mixture.

2. The method of claim 1, wherein flowing the gas mixture further comprises:
flowing an oxygen containing gas accompanying with the SiF₄ gas into the reactor.

3. The method of claim 2, wherein flowing the oxygen containing gas further comprises:
flowing the oxygen containing gas at a flow rate between about 0 to about 200 sccm.

4. The method of claim 1, wherein flowing the gas mixture further comprises:
flowing at least one carrier gas into the reactor.

5. The method of claim 4, wherein the carrier gas is selected from a group consisting of H₂, N₂, Ar, Xe, He and Kr.

6. The method of claim 1, wherein flowing the gas mixture further comprises:
flowing a carbon fluorine containing gas accompanying with the SiF₄ gas into the reactor.

7. The method of claim 6, wherein the carbon fluorine containing gas is selected from a group consisting of CH₂F₂, CHF₃, CH₃F, C₂F₆, CF₄ and C₃F₈.

8. The method of claim 1, wherein flowing the gas mixture further comprises:
flowing the SiF₄ at a flow rate between at 5 sccm to about 500 sccm.

9. The method of claim 1, wherein etching further comprises:
maintaining a process pressure at between about 10 mTorr to about 500 mTorr;
controlling substrate temperature between about 0 degrees Celsius to about 65 degrees Celsius; and
applying a plasma power between about 100 Watts to about 800 Watts.

10. The method of claim 1, wherein the dielectric barrier layer a carbon and nitrogen containing silicon film.

11. The method of claim 1, wherein the dielectric bulk insulating layer is a carbon-containing silicon oxide layer.

12. The method of claim 1, further comprising:
removing the exposed dielectric barrier layer; and
exposing an underlying conductive layer disposed below the dielectric barrier layer on the substrate.

13. A method for etching a dielectric barrier layer in a dual damascene structure, comprising:
providing a substrate having a portion of a dielectric barrier layer exposed through a dielectric bulk insulating layer in a reactor, wherein the dielectric barrier layer is a carbon and nitrogen containing silicon film;
flowing a gas mixture containing SiF₄ gas into the reactor; and
etching the exposed portion of the dielectric barrier layer in a presence of a plasma formed from the gas mixture.

14. The method of claim 13, wherein flowing the gas mixture further comprises:
flowing a carrier gas into the reactor, wherein the carrier gas is selected from a group consisting of H₂, N₂, Ar, He, and Kr.

15. The method of claim 13, wherein flowing the gas mixture further comprises:
flowing a carbon fluorine containing gas into the reactor, wherein the carbon fluorine containing gas is selected from a group consisting of CH₂F₂, CHF₃, CH₃F, C₂F₆, CF₄ and C₃F₈.

16. The method of claim 15, wherein flowing the gas mixture further comprises:
flowing an oxygen containing gas into the reactor, wherein the oxygen containing gas is selected from a group consisting of O₂, N₂O, NO₂, and CO₂.

17. The method of claim 13, wherein the dielectric bulk insulating layer is a carbon-containing silicon oxide.

18. A method for etching a dielectric barrier layer in a dual damascene structure, comprising:
providing a substrate having a portion of a dielectric barrier layer exposed through a dielectric bulk insulating layer and a hardmask layer in a reactor, wherein the dielectric bulk insulating layer is a low-k material and the dielectric barrier layer is a carbon and nitrogen containing silicon film; and
flowing a gas mixture containing SiF₄ gas into the reactor; and
etching the exposed portion of the dielectric layer selectively to the dielectric bulk insulating layer in the presence of a plasma formed from the gas mixture.

19. The method of claim 18, wherein flowing a gas mixture further comprises:
flowing the SiF₄ gas at a flow rate between about 5 sccm to about 500 sccm;
maintaining a process pressure at between about 10 mTorr to about 500 mTorr;
controlling substrate temperature between about 0 degrees Celsius to about 65 degrees Celsius; and
applying a plasma at between about 100 Watts to about 800 Watts.

20. The method of claim 18, wherein the dielectric bulk insulating layer is a carbon containing silicon oxide layer.
